(19) United States
(12) Patent Application Publication
(10) Pub. No.: US 2018/0013099 A1
(43) Pub. Date: Jan. 11, 2018

(54) ELECTRO-OPTICAL DEVICE STACK

(71) Applicant: Nederlandse Organisatie voor toegepast- natuurwetenschappelijk onderzoek TNO, 's-Gravenhage (NL)

(72) Inventor: Stephan Harkema, 's-Gravenhage (NL)

(21) Appl. No.: 15/546,532

(22) PCT Filed: Jan. 19, 2016
(86) PCT No.: PCT/NL2016/050044

§ 371 Date: Jul. 26, 2017

(30) Foreign Application Priority Data
Jan. 29, 2015 (EP) 15152984.9

(51) Int. Cl. H01L 51/52; H01L 51/56

(52) U.S. Cl. CPC H01L 51/5268; H01L 51/5275; H01L 51/56; H01L 51/5253; H01L 51/5271; H01L 2251/5369

(57) ABSTRACT

An optical scattering layer (10) comprising a birefringent matrix material (11) and a plurality of scattering particles (12) dispersed in the matrix material (11). The scattering particles (12) have a particle refractive index (“np”) that for visible light matches the ordinary refractive index (“no”). By matching the refractive index of the scattering particles with one of the refractive indices of the birefringent matrix material, anisotropic scattering is obtained.

### TECHNICAL FIELD AND BACKGROUND

The present disclosure relates to an electro-optical device stack comprising an optical scattering layer, an electronic device comprising the electro-optical device stack, and a method for manufacturing the optical scattering layer.

An optical scattering layer may alter (scatter) a direction of light traveling though the layer. This can improve out-coupling e.g. in an electro-optical device stack wherein light is redirected to outside the device. For example, out-coupling by means of a scattering layer can be advantageous to raise the efficiency of an electro-optical device such as an OLED. Without such layer, reaching an efficiency of 100 lm/W or higher is difficult. However, the scattering layer may result in haziness. For example, when a transparent device is provided, it can be disadvantageous that a specular transmittance is reduced by adding the scattering layer. For example, when a reflecting back surface is provided, it can be disadvantageous that a mirror-like appearance of the device is lost by adding the scattering layer.

Accordingly, it is desired to provide an optical scattering layer that can improve out-coupling without the appearance of haziness.

### SUMMARY

A first aspect of the present disclosure provides an optical scattering layer. The optical scattering layer comprises a birefringent matrix material having an ordinary refractive index in an in-plane direction of the optical scattering layer and an extraordinary refractive index in a normal direction perpendicular to the plane of the optical scattering layer. The optical scattering layer further comprises a plurality of scattering particles dispersed (dissolved or otherwise spread) in the matrix material. The scattering particles have a particle refractive index that for visible light matches the ordinary refractive index of the optical scattering layer.

Without being bound by theory, the following is observed. By a mismatch between the refractive index of the scattering particles and the refractive index of the birefringent matrix material in the normal direction, light having an electric field component in that normal direction may be scattered by the particles. It is noted this can affect light propagating at a relatively high angle with respect to the normal since the electric field component is perpendicular to the direction of propagation. At the same time by matching the refractive index of the scattering particle with a refractive index of the birefringent matrix in an in-plane direction of the optical scattering layer, light propagating in the normal direction, i.e. having electric field components in the in-plane direction of the optical layer, is minimally affected by the scattering particle. Refraction of incident light from air into a denser medium may result in propagation in this medium at an angle of transmitted light that is lower than the incident angle. As such, the specular transparency of the birefringent scatter can remain high, even at higher angles. Accordingly an optical scattering layer is provided that can improve out-coupling by scattering light at relatively high angles with respect to the normal, while minimizing the appearance of haziness, when the optical scattering layer is viewed from the front, at relatively low angles with respect to the normal.

Additional synergetic advantages may be achieved by one or more combinations of the following features. By providing a uniaxial birefringent matrix material having its optic axis coinciding with the normal direction perpendicular to the plane of the optical scattering layer, the effect on light having normal incidence on the layer can be independent on the polarization of the light. Accordingly, even randomly polarized light propagating at normal incidence (low viewing angles) may be relatively unaffected by the birefringence. By matching the refractive index of the particles with the lowest of the refractive indices of the matrix material, a relatively higher scattering ratio can be achieved between light traveling in different directions, in particular to achieve relatively high scattering at high incidence angles while having relatively low scattering at low or normal incidence angles. By providing the particle refractive index smaller than or equal to the ordinary refractive index, a further optimum scattering difference may be achieved. By providing scattering particles with an isotropic refractive index, it can be easier to match the single refractive index with those of the matrix material independent on an orientation of the scattering particles.

Preferably, the parameters of the materials (e.g. refractive indices, particle size) are chosen to provide a maximum a scattering ratio, e.g. at least five, at least ten, or even more, e.g. at least twenty, or even fifty. A higher scattering ratio may provide better out-coupling with minimal haziness from low viewing angles. Preferably, a size of the particles is of the same order as a wavelength of the light. For example, a diameter of the scattering particles is between 400 and 2500 nanometre, preferably between 500 and 2000 nanometre. By using scattering particles comprising substances that are reactive with water and/or oxygen, the vapour or oxygen transmission rate of the optical scattering layer can be lowered. A synergetic advantage in combination e.g. with organic layers such as used in OLEDs is thus achieved by additionally using the optical scattering layer as moisture and/or oxygen barrier. Preferably scattering particles are selected wherein the reaction with water and/or oxygen does not significantly alter the refractive index of the scattering particles outside the desired limits for matching with the matrix material. Alternatively, or in addition to reactive particles, inert scattering particles can be used that do not react with water and/or oxygen thus keeping a constant refractive index.

The optical scattering layer can be used e.g. in an electro-optical device stack for an electronic device. For example, the device stack may comprise an electro-optical layer configured to emit light to outside the device stack via the optical scattering layer. The optical scattering layer can in principle be positioned anywhere in a path of the light.

The device stack may comprise or form an optical micro-cavity with reflective or semi-reflective interfaces. By providing the scattering layer anywhere inside the micro-cavity, light may pass through the scattering layer multiple times, wherein the light is re-directed in each pass. Alternatively, or in addition the scattering layer can be provided at an interface of the micro-cavity. Reflection on the interface of the optical scattering layer may e.g. be affected by the refractive index experienced by the evanescent electric field of the light extending into the optical scattering layer and depending on a direction of the light. Accordingly, this can have a similar effect of re-directing or preferentially reflecting the light on each pass in the micro-cavity. Accordingly, by providing the optical scattering layer inside the microcavity and/or at an interface of the microcavity scattering efficiency can be improved compared to a device wherein light encounters the scattering layer only once.

The optical scattering layer can be used e.g. in top emission, transparent and bottom emission devices and may serve as barrier layer when coupled with a single inorganic dense layer, such as SiO2, Al2O3, SiN and other materials known to the expert, or sandwiched between two of such dense inorganic layers, or sandwiched between two or more arrangements of one or more layers. A birefringent out-coupling layer with scatter particles that matches the refractive index of the matrix normal to the surface will enable scattering to be less visible when viewed from a range of angles. By tuning the refractive indices, viewing from the front, could provide less haziness, e.g. better transparency or improved more mirror-like appearance (since scattering is suppressed), while at the higher angles scattering would enable a higher out-coupling. For example, an OLED stack may emit light in all directions into the substrate, also at high angles. Depending on the OLED this may be between e.g. 20-60% of the total. By scattering this light at high angles, out coupling can be improved,

A second aspect of the present disclosure provides a method for manufacturing an optical scattering layer, e.g. according to the first aspect. The method comprises mixing a plurality of scattering particles into a liquid (e.g. crystalline) matrix material, depositing and hardening the mixture as a layer. The matrix material is provided to have an ordinary refractive index in an in-plane direction of the optical scattering layer and an extraordinary refractive index in a normal direction perpendicular to a plane of the optical scattering layer, while the dispersed scattering particles have a particle refractive index that for visible light matches the ordinary refractive index

### BRIEF DESCRIPTION OF DRAWINGS

These and other features, aspects, and advantages of the apparatus, systems and methods of the present disclosure will become better understood from the following description, appended claims, and accompanying drawing wherein:

FIGS. 1A and 1B schematically illustrate light propagating at different angles through a piece of an optical scattering layer;

FIGS. 2A and 2B schematically illustrate embodiments of electro-optical device stack including an optical scattering layer;

FIG. 3A schematically illustrates another embodiments of an electro-optical device stack;

FIG. 3B schematically illustrates an optical scattering layer with a concentration of scattering particles;

FIGS. 4A and 4B schematically illustrate methods for manufacturing an optical scattering layer;

FIGS. 5-7 show graphs illustrating the dependence of particle scattering cross-section as a function of various parameters.

### DESCRIPTION OF EMBODIMENTS

Unless otherwise defined, all terms (including technical and scientific terms) used herein have the same meaning as commonly understood by one of ordinary skill in the art to which this invention belongs as read in the context of the description and drawings. It will be further understood that terms, such as those defined in commonly used dictionaries, should be interpreted as having a meaning that is consistent with their meaning in the context of the relevant art and will not be interpreted in an idealized or overly formal sense unless expressly so defined herein. In some instances, detailed descriptions of well-known devices and methods may be omitted so as not to obscure the description of the present systems and methods. Terminology used for describing particular embodiments is not intended to be limiting of the invention. As used herein, the singular forms “a”, “an” and “the” are intended to include the plural forms as well, unless the context clearly indicates otherwise. The term “and/or” includes any and all combinations of one or more of the associated listed items. It will be understood that the terms “comprises” and/or “comprising” specify the presence of stated features but do not preclude the presence or addition of one or more other features. It will be further understood that when a particular step of a method is referred to as subsequent to another step, it can directly follow said other step or one or more intermediate steps may be carried out before carrying out the particular step, unless specified otherwise. Likewise it will be understood that when a connection between structures or components is described, this connection may be established directly or through intermediate structures or components unless specified otherwise. All publications, patent applications, patents, and other references mentioned herein are incorporated by reference in their entirety. In case of conflict, the present specification, including definitions, will control.

The refractive index “n” of a material can be defined as n=c/v, wherein “c” is the speed of light in vacuum and “v” is the speed of light in the material, more accurately the phase velocity of the light. Without being bound by theory it is noted that the refractive index of a material can depend on a structure of the material and the manner in which the oscillating electromagnetic field of light traveling through the material couples to that structure. Depending on the material, the refractive index of a material can be isotropic, i.e. the same for light propagating in any direction, or anisotropic, i.e. different for different directions of the propagating light and its polarization.

As used herein, the phrase “refractive index in a direction” means the effective ratio c/v of linearly polarized light having its polarization, i.e. the direction of the electric field component in that direction. For most naturally occurring materials, the influence of the magnetic component at optical frequencies can be neglected and the electric field component is dominant. For example a crystalline structure of a material may couple differently to the light depending on a direction of the electric field. It is noted that the electric field is perpendicular to a propagation direction of the light. Accordingly, the refractive index for light traveling in a certain direction is actually determined by the material structure in directions perpendicular to the propagation of the light.

The phrase “birefringent material” is used to indicate that the material has a refractive index which is different along various axes of the material. Birefringence can be quantified e.g. as the maximum difference between the extraordinary and ordinary refractive indices of the material: Δn=ne−no. For example, a uniaxial birefringent material has an extraordinary refractive index along an optic axis and an contribution of the ordinary refractive index in all directions perpendicular to the optic axis. Uniaxial birefringence can be classified positive or negative according to the sign of Δn=“ne”−“no”. For example positive birefringence means that “ne” larger than “no”. Historically, and as used herein, the term birefringence may include also materials that are characterized by more than two refractive indices, e.g. biaxial materials having three principal axes. Sources of birefringence may include anisotropic crystal formation, stress induced birefringence, birefringence induced by electric fields (Kerr effect) or magnetic fields (Faraday effect) self or forced alignment of molecules, e.g. thin films of amphiphilic molecules such as lipids, surfactants or liquid crystals.

The refractive index is generally dependent on the wavelength of the light (“dispersion”). Unless otherwise indicated, the refractive index as used herein is that for visible light, i.e. having a wavelength between 390 to 700 nanometre, either with negligible wavelength dependence and/or, if a comparative value for the refractive index is mentioned, the comparison holds true for the entire visible wavelength range. Furthermore, unless otherwise indicated, the used refractive index is that for normal light intensities, i.e. without taking into account non-linear effects which may occur at high intensities. For randomly or circularly polarized light, the refractive indices affecting the light can be determined by splitting the contribution according to the directions of the two polarizations of the light. In a birefringent material this may cause one polarization component of the light to be refracted differently than the other polarization component.

Scattering is a process by which the spatial distribution of a beam of radiation is changed. For example, light can be scattered by interaction with particles dispersed in a medium. The scattering cross-section, i.e. probability that light will be scattered can be dependent on the particle size e.g. relative to the wavelength of the light. Furthermore, it can be dependent on a difference in refractive index between the particle and the surrounding medium, e.g. matrix material. In a birefringent matrix material, as used herein, the difference between the refractive index of the matrix and the particle can be different depending on the direction of the propagating light and its electric field. This effect can be used to obtain different degrees of scattering in different directions. The difference between scattering cross-section of light propagating in different directions is referred herein as the “scattering difference”. The ratio between scattering cross-section of light in different directions is referred herein as the “scattering ratio” or “contrast”.

According to one definition, a material may be considered birefringent, especially to provide a desired effect as described herein, if a maximum difference, between refractive indices in the material is at least 0.01, preferably more, e.g. at least 0.05, at least 0.1, at least 0.2, at least 0.3, or at least 0.5. For the current purposes, the more birefringent the matrix material, the higher can be the scattering difference of the light interacting with particles in the matrix material from different directions.

According to one definition, two refractive indices are considered to match if a difference between the refractive indices is at most 0.05, preferably less, e.g. at most 0.02, preferably even less, e.g. equal. For the current purposes, the more equal the refractive indices of the scattering particle and at least one of the refractive indices of the material, the less scattering may occur for light having it polarization in a direction of the matching refractive indices. Accordingly, a higher scattering contrast or ratio can be achieved.

The invention is described more fully hereinafter with reference to the accompanying drawings, in which embodiments of the invention are shown. This invention may, however, be embodied in many different forms and should not be construed as limited to the embodiments set forth herein.

Rather, these embodiments are provided so that this disclosure will be thorough and complete, and will fully convey the scope of the invention to those skilled in the art. The description of the exemplary embodiments is intended to be read in connection with the accompanying drawings, which are to be considered part of the entire written description. In the drawings, the absolute and relative sizes of systems, components, layers, and regions may be exaggerated for clarity. Embodiments may be described with reference to schematic and/or cross-section illustrations of possibly idealized embodiments and intermediate structures of the invention. In the description and drawings, like numbers refer to like elements throughout.

Relative terms as well as derivatives thereof should be construed to refer to the orientation as then described or as shown in the drawing under discussion. These relative terms are for convenience of description and do not require that the system be constructed or operated in a particular orientation unless stated otherwise.

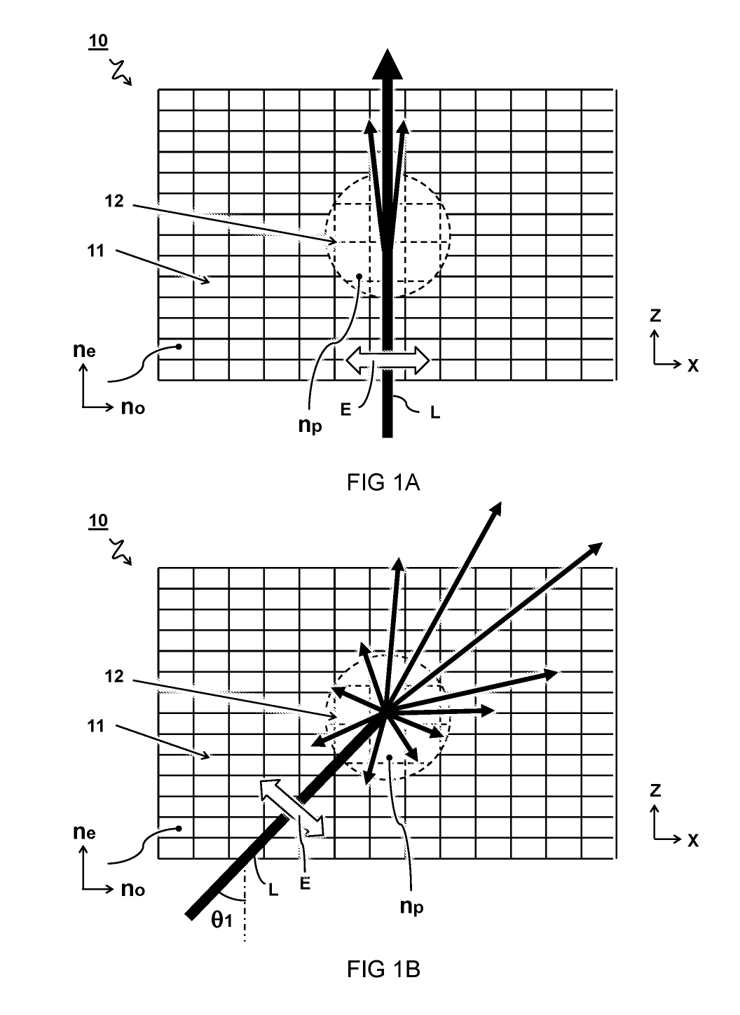

FIGS. 1A schematically illustrates light “L” propagating at a normal incidence angle through a piece of an optical scattering layer 10. FIGS. 1B schematically illustrates the same light “L” propagating at a larger incidence angle θ1.

The optical scattering layer 10 comprises a birefringent matrix material 11 having an ordinary refractive index “no” in an in-plane direction X of the optical scattering layer 10 and an extraordinary refractive index “ne” in a normal direction Z perpendicular to a plane of the optical scattering layer 10. A plurality of scattering particles 12 are dispersed in the matrix material 11 (the current figure illustrates one particle). The scattering particles 12 have a particle refractive index “np” that matches the ordinary refractive index “no”.

As illustrated by the figures, light propagating at normal incidence angle (FIG. 1A) may experience relatively low scattering by the particle 12 due to the matching refractive indices “no” and “np” in the direction of the electric field “E” indicated by the white arrow. It is noted that for a uniaxial material 11, the refractive index “no” is also in the direction “Y” (not shown here). Accordingly, also for the other polarization of the light than shown the refractive indices can be matching. On the other hand light propagating at higher incidence angle θ1 (FIG. 1B) may experience relatively high scattering by the particle 12 due to the mismatching refractive indices “ne” and “np”. The higher the angle of incidence θ1, the higher the contribution of the mismatching refractive index “ne”.

In one embodiment, a difference between the second and ordinary refractive indices “ne” “no” is at least 0.1, e.g. for visible light. In one embodiment, a relative difference |“no”−“ne”|/“no”+“ne” between the first and extraordinary refractive indices is at least 0.05. In one embodiment for visible light a refractive index difference “no”−“np” is at most 0.05. In one embodiment, a relative difference |np−“ne”|np+“ne” between the first and particle refractive indices is at most 0.02. In one embodiment, the particle refractive index “np” is isotropic. In one embodiment, the particle refractive index “np” is smaller than or equal to the ordinary refractive index “no”. In one embodiment, a difference “no”−“np” between the ordinary refractive index “no” and the particle refractive index “np” is at least 0.01.

In one embodiment, the birefringent matrix material 11 is uniaxial having its optic axis coinciding with the normal direction Z perpendicular to the plane XY of the optical scattering layer 10. In one embodiment, the extraordinary refractive index “ne” is in the normal direction Z perpendicular to a plane XY of the optical scattering layer 10 and wherein the ordinary refractive index “no” is both in the in-plane direction X,Y and in a third direction Y wherein the first and third directions XY are in-plane of the optical scattering layer 10. In one embodiment, the extraordinary refractive index “ne” is larger than the ordinary refractive index “no”, i.e. a positive uniaxial birefringent material.

In one embodiment, an average or median scattering cross-section σ1 of the scattering particles 12 in the optical scattering layer 10 for light propagating in a direction perpendicular to a plane of the optical scattering layer 10 is relatively low, e.g. less than 10⁻¹ μm², preferably less than 10⁻² μm², more preferably less than 10⁻³ μm², e.g. between 10⁻¹² μm² and 10⁻⁴ μm² for visible light in a wavelength range between 390 to 700 nanometre. In one embodiment, a particle size, refractive index “np”, and concentration of the scattering particles 12 is selected in relation to the refractive index “no” of the matrix material 11 and a layer thickness of the optical scattering layer 10 such that less than 10% of the visible light traversing the optical scattering layer 10 at normal incidence angle is scattered in the optical scattering layer 10, preferably less than 1%, more preferably less than 0.1%. For example, for the current purposes, a part of the light can be considered as “scattered” when its direction of propagation is changed by more than 10 degrees by interaction with one or more scattering particles 12. For example, less than 10% of the visible light traversing the optical scattering layer at normal incidence undergoes a directional change of more than 10 degrees. More in general, scattering can be defined as a physical process where light is forced to deviate from a straight trajectory by one or more paths due to localized non-uniformities in the medium through which it passes.

In one embodiment, an average or median scattering cross-section σ2 of the scattering particles 12 in optical scattering layer 10 for light propagating in an in-plane direction of the optical scattering layer 10 is relatively high, e.g. more than 10⁻¹ μm², preferably more than 1 μm², more preferably more than 10 μm², e.g. between 10 μm² and 1000 μm² for visible light in a wavelength range between 390 to 700 nanometre. In one embodiment, a particle size, refractive index “np”, and concentration of the scattering particles 12 is selected in relation to the refractive indices “no” and “ne” of the matrix material 11 and a layer thickness of the optical scattering layer 10 such that more than 10% of the visible light traversing the the optical scattering layer 10 at an incidence angle of 45 degrees is scattered in the optical scattering layer 10, preferably more than 25%, more preferably more than 50%.

In one embodiment, a ratio or scattering contrast between a scattering cross-section σ2 of the scattering particles 12 in the birefringent matrix material 11 for visible light propagating in an in-plane direction X,Y of the optical scattering layer 10 versus a scattering cross-section σ1 of the scattering particles 12 in the birefringent matrix material 11 for visible light propagating in a direction Z perpendicular to the plane XY of the optical scattering layer 10 is more than three, preferably more than five, or even more than ten.

In one embodiment, the matrix material 11 comprises a photo-activated bi-refringent material. In one embodiment, the matrix material 11 comprises a stretched and/or compressed foil. Also other ways can be envisaged to control and/or determine refractive indices of a matrix material.

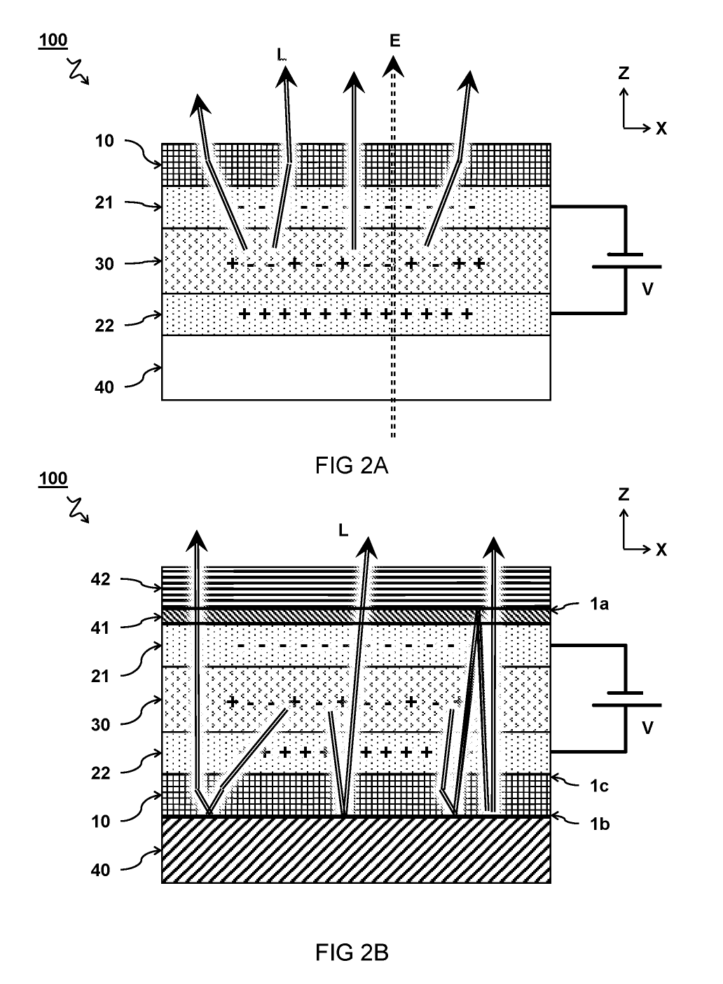

FIGS. 2A and 2B schematically illustrates a embodiments of an electro-optical device stack 100 comprising an optical scattering layer 10 as described herein. The electro-optical device stack 100 further comprises an electro-optical layer 30 configured to emit or receive light “L” to or from outside the device stack 100 via the optical scattering layer 10. Preferably, the optical scattering layer 10 is close to the electro-optical layer 30 to enable a higher out-coupling. In one embodiment, the electro-optical layer 30 is sandwiched between electrodes, e.g. a cathode 21 and an anode 22 for applying a voltage “V”. Also further conductive layers may be included between the electrodes, e.g. a hole injection layer and/or an electron injection layer. In one embodiment, the device stack includes a substrate 40, e.g. comprising a foil or metal. In another embodiment, the positions of the anode and electrode may be interchanged. The electrodes may also comprise multiple layers.

In one embodiment, as shown in FIG. 2A, all layers including the electrodes 21,22, and substrate 40 are transparent to visible light thus providing a transparent device stack 100. Advantageously, by using an anisotropic scattering layer 10 in a transparent device stack 100, external light “E” may propagate through the device stack 100 at low incidence angles (normal viewing angles) with minimal scattering, while light “L” generated in the electro-optical layer 30 at higher angles can be scattered to improve out-coupling. In one embodiment, the electro-optical layer is a semiconducting organic layer, e.g. providing an OLED device.

In one embodiment, as shown in FIG. 2B, the electro-optical device stack 100 comprises a multi-layered structure having at least two reflective interfaces 1a, 1b with the electro-optical layer 30 therein between. In one embodiment, at least one of the reflective interfaces 1a is semi-transparent to form a microcavity in between the two reflective interfaces 1a, 1b and/or 1a, 1c.

For example, in a top-emission device, as shown, the reflective interface 1a can be semi-transparent and the reflective interface 1b can be fully reflective. For example, in a bottom -emission device (not shown), the reflective interface 1a can be fully reflective and the reflective interface 1b can be semi-transparent, e.g. a transparent substrate. For example, in a transparent device with cavity (not shown), both reflective interfaces 1a and 1b can be semi-transparent. For example, a semi-transparent interface 1a and/or 1b is configured to reflect between twenty and ninety-nine percent of light, preferably between fifty and ninety percent of light or between sixty and eighty percent of light, e.g. light emitted and/or absorbed by the electro-optical layer, e.g. visible light.

In one embodiment, the optical scattering layer 10 is provided at an edge or interface 1b, 1c of the microcavity. In one embodiment, the scattering layer is provided between reflective interfaces 1a, 1b. Alternative or in addition, the interface 1c between the scattering layer 10 and e.g. one of the electrodes 22 may form a reflective surface of the microcavity. Reflection on the interface 1c may e.g. be affected by the refractive index experienced by the evanescent electric field of the light L extending into the optical scattering layer 10 and depending on a direction of the light L.

The more reflective the semi-transparent layer, the more times light may pass the optical scattering layer in the cavity on average. In one embodiment, the electro-optical layer 30 is configured to emit or absorb light L inside the microcavity, wherein the light L is reflected between the reflective interfaces 1a, 1b of the microcavity, wherein the reflectivity of the interfaces is configured such that light L on average encounters the optical scattering layer 10 more than once, e.g. at least twice before exiting the microcavity via the semi-transparent interface 1a. For example the light may travel through the optical scattering layer at least twice and/or be reflected off an interface of the optical scattering layer at least twice. The light may also encounter the optical scattering layer 10 on average more than twice, e.g. at least three, four, five or more times, the higher the reflectivity of the semi-transparent interface.

It is noted that even for a weak cavity (low reflectivity of the semi-transparent interfaces), the optical scattering layer 10 may influence the (dominant) mode in the cavity. Accordingly, also for a relatively low reflection of e.g. ten or twenty percent, the optical scattering layer may advantageously affect performance of the device. For efficiency, preferably the cavity interfaces are relatively distanced to allow constructive interference of a cavity mode. Typically, this means that the cavity interfaces are distanced at a multiple of half times the wavelength of the light L for which the cavity is designed. The distance between the cavity interfaces may also be adjusted depending on any phase shifts of the light which may occur at the reflective interfaces.

The application of a birefringent scattering layer is found to be particularly useful at higher distances between the cavity interfaces, e.g. wherein the distance between the reflective interfaces is at least one wavelength of the light L, at least one-and-half wavelength of the light L, or more. It is found that, without the optical scattering layer, light may be emitted relatively inefficiently especially at higher cavity distances.

In one embodiment, the electrodes 21,22 are disposed in the microcavity and transparent to visible light. In one embodiment, the multi-layered structure comprises a metallic or metalized substrate to form one of the reflective interfaces lb. In one embodiment, one of the reflective interfaces la is formed by an interface between an inorganic and an organic barrier layer 41,42. In another embodiment, one of the electrodes is semi-transparent thus forming one of the reflective interfaces. The electro-optical device stack 100 as described herein may find application e.g. in a display of an electronic device.

Alternative, or in addition to the embodiments shown, in one embodiment the optical scattering layer is applied onto an inorganic layer. In one embodiment, the optical scattering layer is covered by an inorganic barrier layer. In one embodiment, a barrier layer is provide between the substrate and the optical scattering layer. Also other variations of layers and interfaces are possible.

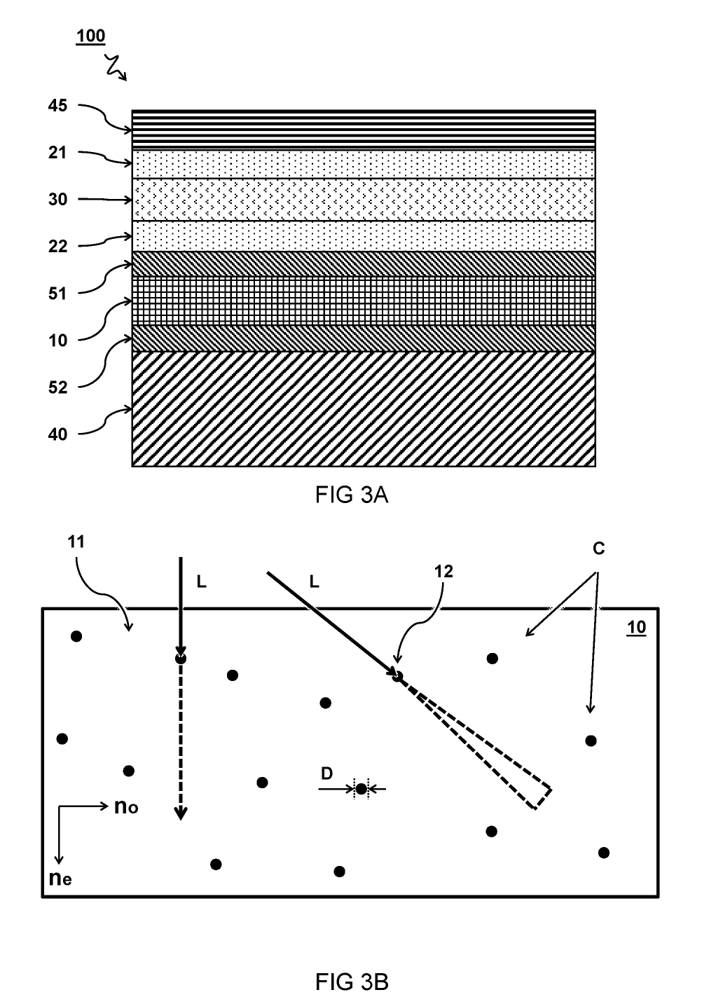

FIG. 3A schematically illustrates another embodiments of an electro-optical device stack including an optical scattering layer 10. In one embodiment, scattering particles in the optical scattering layer 10 are reactive with water and/or oxygen for substantially preventing water and/or oxygen transmission though the optical scattering layer 10. In one embodiment further organic or inorganic layers 51,52 are provided to improve the barrier properties. In one embodiment layers 51,52 of inorganic material, e.g. SiN, are provided on one or both sides of the optical scattering layer 10. In one embodiment, the optical scattering layer 10 with or without further barrier layers provides a water vapour transmission rate below 10⁻⁵ g/m²/day. Also on a top side of the stack 100 one or more barrier layers 45 can be provided.

FIG. 3B schematically illustrates an optical scattering layer 10 with a concentration “C” of scattering particles 12 in a matrix material 11. In one embodiment, a diameter of the scattering particles 12 is between 500 and 2000 nanometre. In one embodiment, a concentration of the scattering particles 12 and a thickness of the optical scattering layer 10 are configured to provide a density of between 10⁴ and 10¹⁰ particles per square centimetre of the optical scattering layer 10, preferably between 10⁵ and 10⁷ .

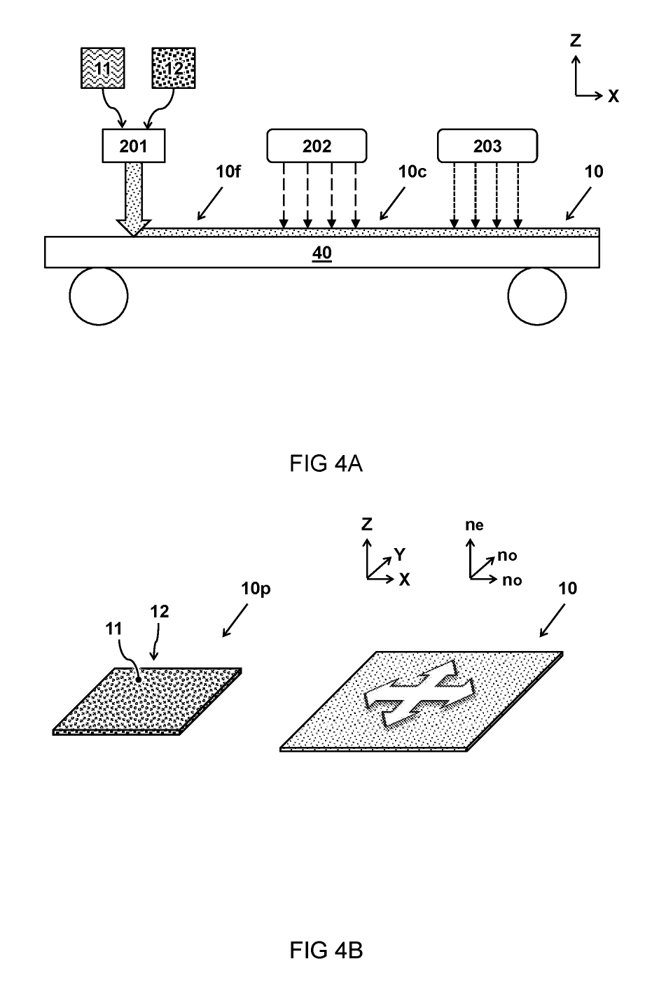

FIGS. 4A schematically illustrates an embodiment of a method for manufacturing an optical scattering layer 10. The method comprises mixing a plurality of scattering particles 12 into a liquid matrix material 11. The mixture is deposited as a layer to solidify or harden, e.g. by evaporating a solvent, by cooling, by (photo-induced) polymerization, etc. Simultaneously or sequentially, a birefringent property is induced in the matrix material 11 wherein the scattering particles 12 have a particle refractive index that for visible light matches one of the refractive indices of the matrix material.

In one embodiment, the birefringent property is induced in the matrix material by aligning liquid crystalline monomers in the matrix material and freezing the alignment into a rigid network by photo-activation. In one embodiment, the matrix material 10 is provided on a photo-alignment layer (not shown). In one embodiment, the photo-alignment layer comprises polymers that are formed by anisotropic dimerization.

In one embodiment a solution layer 10f is deposited on a substrate 40 by a deposition device 201. In one embodiment the layer 10f of solution film is dried by an oven 202 while molecules in the solution are aligned, e.g.

by annealing. In one embodiment the dried film 10c is cured by irradiation e.g. by a UV lamp 203.

Reference is made for example to WO2009086911A1 disclosing some photoactive birefringent material, also known as reactive mesogens or RMs. RMs can be used to make optical films, like compensation, retardation or polarisation films, e.g. for use as components of optical or electro-optical devices like LC displays, through the process of in-situ polymerisation. The optical properties of the films can be controlled by many different factors, such as mixture formulation or substrate properties. The optical properties of the film can in particularly be controlled by changing the birefringence of the mixture. The RM film may be formed as polymerisable material, preferably a polymerisable liquid crystal material, optionally comprising one or more further compounds that are preferably polymerisable and/or mesogenic or liquid crystalline. The RM film may be formed as an anisotropic polymer obtained by polymerising a polymerisable LC material preferably in its oriented state in form of a thin film.

While in some embodiments it is foreseeable that the photoactive birefringent layer may be provided without a pre-alignment layer, for example, by suitable physical preparation of a metalized plastic (i.e. rubbing); preferably, the photoactive birefringent layer is provided on a photo-alignment layer, in a way that alignment is provided by the photo-alignment layer having a function constructed for the purpose of alignment. In this respect, reference is made to the materials described in Y. Kurioz, “P-128: Orientation of a Reactive Mesogen on Photosensitive Surface” Volume 38, Issue 1, pages 688-690, May 2007 wherein photoaligning polymers are discussed that contain derivatives of cinnamic acid in the side fragments of different main chains (polyvinylalcohol, polysiloxane, cellulose). The photoaligning properties of these materials are caused by anisotropic dimerization of side fragments at irradiation with polarized UV light and possible trans-cis isomerisation of the cinnamoil fragments. The cellulose-based cinnamate polymers possess photosensitivity and provide a high quality alignment of most commercial nematic LC mixtures after UV exposure.

FIG. 4B schematically illustrates another or further method for manufacturing an optical scattering layer wherein the birefringent property is induced in the matrix material 11 by stretching and/or compressing the matrix material 11. For example by stretching a polymer foil, a birefringent property can be induced. One embodiment comprises applying mechanical stress to the optical scattering layer 10 while monitoring an amount of scattering through the layer 10, e.g. at normal incidence. In one embodiment, the mechanical stress is applied, e.g. the foil stretched, until a minimum amount of scattering is observed. At this minimum, the ordinary refractive index “no” of the matrix material 11 may be matching that of the scattering particles 12. Also other processes for inducing or controlling birefringence may be performed as a function of scattering to obtain matching refractive indices.

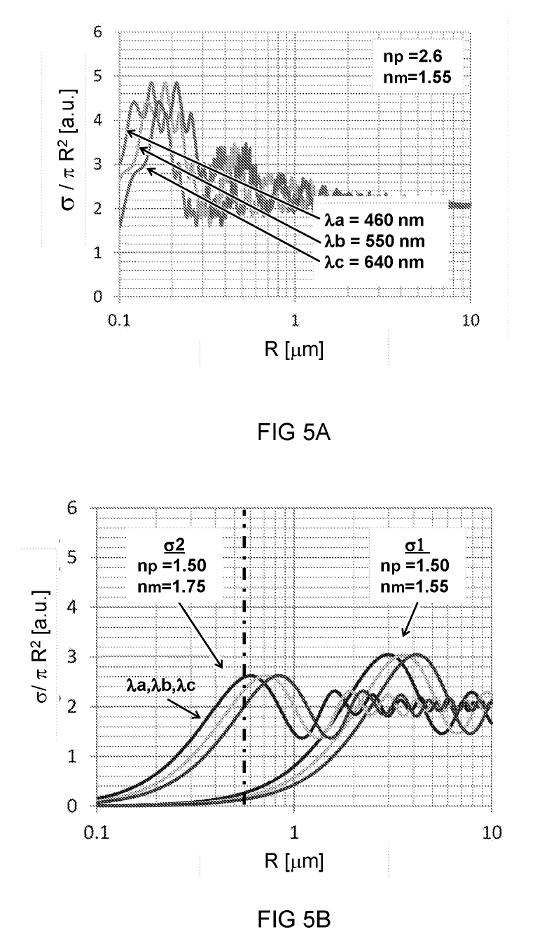

FIG. 5A shows a reference calculation for particles with particle refractive index “np”=2.6 in a matrix with refractive index “nm”=1.55. For example TiO2 particles in a PEN foil. The graph shows the scattering cross section “σ” (here normalized by the geometrical area of the particle π R² as a function of the radius “R” of the particles (half the diameter). In this figure and the following, three similar graphs are shown corresponding to different wavelengths of the light. In particular, the wavelengths λa, λb, λc correspond to wavelengths of the light at 460 nm, 550 nm, 640 nm, respectively (wavelength in vacuum).

FIG. 5B shows a calculation for particles with “np”=1.50 in an matrix with refractive index “nm”=1.55 (left three graphs) and in a matrix with refractive index “nm”=1.75 (right three graphs). This may illustrate the difference in scattering cross-section for different refractive indices in a matrix material. For example, it may be observed that for particle radius R=600 nm (dash-dotted line), the scattering cross-section σ2 for the higher refractive index mismatch (1.50 vs 1.75) is much larger than the scattering cross-section of for the lower refractive index mismatch (1.50 vs 1.55). Such a situation may occur e.g. in an optical scattering layer 10 having a birefringent matrix material 11 with “no”=1.55 and “ne”=1.75. For example, a PEN foil can be stretched to provide a birefringent matrix material with these refractive indices. The radius R of the particle as shown in these graphs corresponds to half a diameter of the particles. Of course also non-spherical particles can be used, in which case the diameter refers to a largest cross-section diameter of the particles.

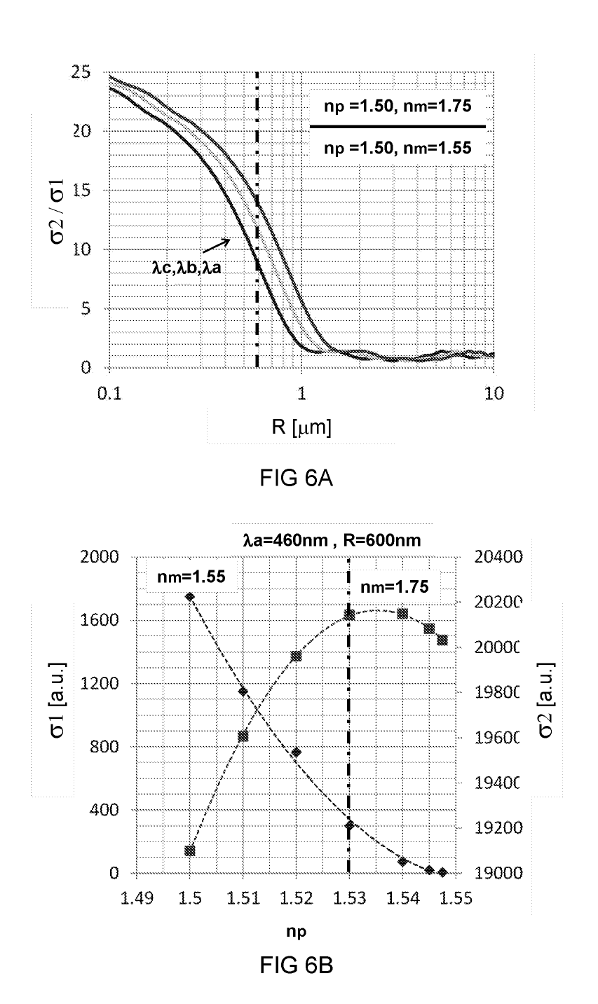

FIG. 6A shows a contrast ratio σ2/σ1 of scattering cross-section for particles with n=1.5 in a birefringent matrix, using the two refractive indices of PEN (1.55 and 1.75), as shown in FIG. 5B. It is noted that the graph shows the largest contrast ratio for particles with radius R below 1 micron. Optimal for scattering at high angles in PEN (high refractive index) is ˜0.5-0.8 microns, meaning a contrast ratio >4. If 600 nm particles are taken, at the peak for blue light, the contrast for blue light (λa) is ˜8.5.

FIG. 6B shows calculations for the scattering intensity at 0 degrees, as a measure for scattering by particles with index close to that of the matrix (“nm”=1.55) and with mismatching refractive index (“nm”=1.75). For the chosen size of R=600 nm, it seems that 0.02 difference (at the dash-dotted line “np”=1.53) is best for blue light As and gave the highest contrast σ2/σ1 for scattering intensity (factor 67).

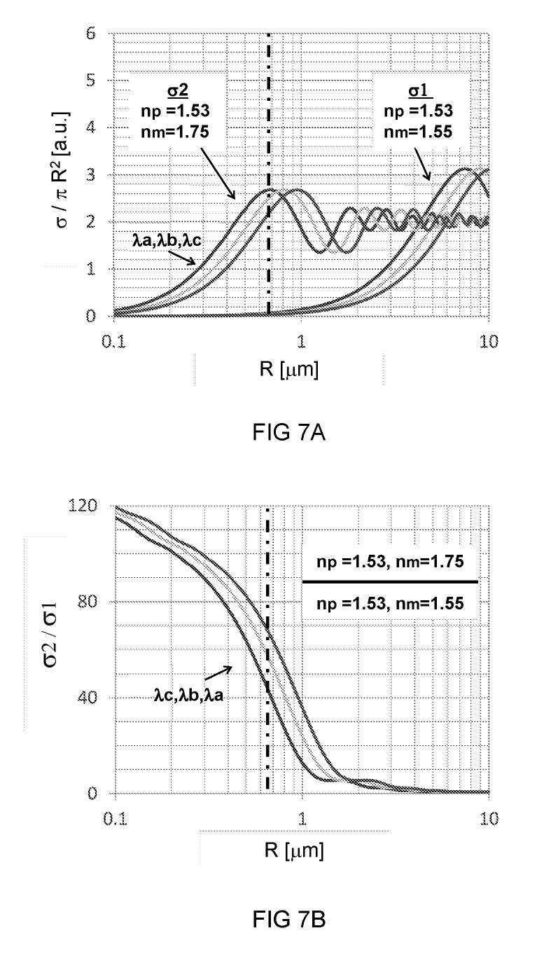

FIG. 7A shows similar graphs as FIG. 5B but for particle refractive index “np”=1.53 in matrix refractive indices “nm”=1.55 and 1.75.

FIG. 7B shows the corresponding contrast ratio graphs. The graph shows the largest contrast ratio below particle radius R=1 micron. Optimal for scattering at high angles in PEN (high refractive index) is ˜0.8 microns (for blue to red), meaning a contrast ratio >27.5 (for blue) and even up to 55. If 670 nm particles are taken, at the peak for blue light, the contrast for blue light is 41.

It is concluded from the above that materials with a refractive index equal or slightly lower than the matrix's lowest refractive index are most suitable. Particles with lower refractive index than the intended matrix with moderate refractive index “np” of 1.5-1.6 may include for example pure oxides, such as SiO2 (n=1.46); fluorinated PFBMA (n<1.39) J. Am. Chem. Soc. 1998 120 6518; Spherical particles consisting of a mix of nanoparticles of multiple materials, such as SiO2 and TiO2 (n tunable between 1.4 and 1.6) reported for micron sized particles in Adv Mat 2008 20 3268; pure polymer materials; PMMA 1.49; Fluorinated polymers 1.35 and higher; MgF2 1.38-1.385; certain salts (although not typical fillers); borax Na2(B4O5)(OH)4.8(H2O) n˜1.45; epsom salt MgSO4.7(H2O) n˜1.43; ulexite NaCaB5O6(OH)6.5(1120) n˜1.49; doping of polymer nanoparticles with other low index materials, such as silicon oxide; silicon oxide particles with voids can be used as low refractive index filler.

A difference between the refractive index of the matrix and particle is preferably less than 0.05, more preferably less than 0.025 for very transparent scattering layers. Higher refractive index contrast of the particle with the matrix is possible, but a layer formed with this matrix/particle system may exhibit some degree of haziness. In that case materials with lower refractive index may be chosen. In the case that the refractive index of the matrix is increased, other particles become available for the same application, provided that birefringence is maintained.

A particle size can be chosen e.g. for the highest refractive index mismatch (e.g. particle vs matrix), e.g. 670 nm particle with n assumed 1.53 in PEN, which at low viewing angles (no=1.55) will be hardly scattering. At high angles, the index mismatch increases, leading to a factor 40-65 increase in scattering cross-section. At this low haziness at low viewing angles, and high scattering at high angles, scattering will be effective e.g. for application in transparent emissive devices Further application may include solar cells e.g. having a fixed position towards the sun. In this case, an anti-reflective coating that is effective at high angles may be desired.

For the purpose of clarity and a concise description, features are described herein as part of the same or separate embodiments, however, it will be appreciated that the scope of the invention may include embodiments having combinations of all or some of the features described. For example, while embodiments were shown for device stacks including a birefringent scattering layer, also alternative ways may be envisaged by those skilled in the art having the benefit of the present disclosure for achieving a similar function and result. E.g. layers may be added or omitted to provide alternative device stacks. The various elements of the embodiments as discussed and shown offer certain advantages, such as improved efficiency OLED devices without haziness. Of course, it is to be appreciated that any one of the above embodiments or processes may be combined with one or more other embodiments or processes to provide even further improvements in finding and matching designs and advantages. It is appreciated that this disclosure offers particular advantages to OLEDs, and in general can be applied for any application for anisotropic light scattering in a layer.

While the present systems and methods have been described in particular detail with reference to specific exemplary embodiments thereof, it should also be appreciated that numerous modifications and alternative embodiments may be devised by those having ordinary skill in the art without departing from the scope of the present disclosure. For example, embodiments wherein devices or systems are disclosed to be arranged and/or constructed for performing a specified method or function inherently disclose the method or function as such and/or in combination with other disclosed embodiments of methods or systems. Furthermore, embodiments of methods are considered to inherently disclose their implementation in respective hardware, where possible, in combination with other disclosed embodiments of methods or systems. Furthermore, methods that can be embodied as program instructions, e.g. on a non-transient computer-readable storage medium, are considered inherently disclosed as such embodiment.

Finally, the above-discussion is intended to be merely illustrative of the present systems and/or methods and should not be construed as limiting the appended claims to any particular embodiment or group of embodiments. The specification and drawings are accordingly to be regarded in an illustrative manner and are not intended to limit the scope of the appended claims. In interpreting the appended claims, it should be understood that the word “comprising” does not exclude the presence of other elements or acts than those listed in a given claim; the word “a” or “an” preceding an element does not exclude the presence of a plurality of such elements; any reference signs in the claims do not limit their scope; several “means” may be represented by the same or different item(s) or implemented structure or function; any of the disclosed devices or portions thereof may be combined together or separated into further portions unless specifically stated otherwise. The mere fact that certain measures are recited in mutually different claims does not indicate that a combination of these measures cannot be used to advantage. In particular, all working combinations of the claims are considered inherently disclosed.

1. An electro-optical device stack comprising:
an electro-optical layer;
an optical scattering layer comprising:
a birefringent matrix material having an ordinary refractive index in an in-plane direction of the optical scattering layer and an extraordinary refractive index in a normal direction perpendicular to a plane of the optical scattering layer, and
a plurality of scattering particles dispersed in the birefringent matrix material, wherein the plurality of scattering particles have a particle refractive index that matches the ordinary refractive index of the birefringent matrix material; and
at least two reflective interfaces forming a microcavity with the electro-optical layer there between, wherein at least one of the at least two reflective interfaces is semi-transparent,
wherein the optical scattering layer is provided at a position taken from the group consisting of:
inside the microcavity, and
at an interface of the microcavity.

2. The electro-optical device stack according to claim 1, wherein the electro-optical layer is configured to emit or absorb light inside the microcavity,
wherein the light is reflected between the reflective interfaces of the microcavity, and
wherein the reflectivity of the interfaces is configured such that the light on average encounters the optical scattering layer at least twice before exiting the microcavity via the at least one semi-transparent reflective interface of the at least two reflective interfaces.

3. The electro-optical device stack according to claim 1, wherein the birefringent matrix material is uniaxial and having an optic axis coinciding with the normal direction perpendicular to the plane of the optical scattering layer.

4. The electro-optical device stack according to claim 1, wherein the ordinary refractive index matching the particle refractive index is less than the extraordinary refractive index of the birefringent matrix material.

5. The electro-optical device stack according to claim 1, wherein the particle refractive index is isotropic.

6. The electro-optical device stack according to claim 1, wherein a ratio of more than three exists between:
a scattering cross-section of the plurality of scattering particles in the birefringent matrix material for visible light propagating in an in-plane direction of the optical scattering layer, and
a scattering cross-section of the plurality of scattering particles in the birefringent matrix material for visible light propagating in a direction perpendicular to the plane of the optical scattering layer.

7. The electro-optical device stack according to claim 1, wherein a diameter of the plurality of scattering particles is between 500 and 2000 nanometers.

8. The electro-optical device stack according to claim 1, wherein a concentration of the plurality of scattering particles and a thickness of the optical scattering layer are configured to provide a surface density of between 10⁴ and 10¹⁰ particles per square centimetre of the optical scattering layer

9. The electro-optical device stack according to claim 1, wherein the plurality of scattering particles are configured to prevent water and/or oxygen transmission though the optical scattering layer.

10. The electro-optical device stack according to claim 1, wherein the electro-optical layer is made of a semiconducting organic material.

11. The electro-optical device stack according to claim 1, wherein for visible light a difference of at least 0.1 exists between the extraordinary and ordinary refractive indices of the birefringent matrix material.

12. The electro-optical device stack according to claim 1, wherein the plurality of scattering particles have a particle refractive index that for visible light matches the ordinary refractive index within a refractive index difference of at most 0.05.

13. The electro-optical device stack according to claim 1, wherein at least one of the at least two reflective interfaces is configured to reflect between twenty and ninety percent of light emitted or absorbed by the electro-optical layer.

14. An electronic device comprising an electro-optical device stack wherein the electro-optical device stack comprises:
an electro-optical layer;
an optical scattering layer comprising:
a birefringent matrix material having an ordinary refractive index in an in-plane direction of the optical scattering layer and an extraordinary refractive index in a normal direction perpendicular to a plane of the optical scattering layer, and
a plurality of scattering particles dispersed in the birefringent matrix material, wherein the plurality of scattering particles have a particle refractive index that matches the ordinary refractive index of the birefringent matrix material; and
at least two reflective interfaces forming a microcavity with the electro-optical layer there between, wherein at least one of the at least two reflective interfaces is semi-transparent,
wherein the optical scattering layer is provided at a position taken from the group consisting of:
inside the microcavity, and
at an interface of the microcavity.
